(19) United States
(12) Patent Application Publication
(10) Pub. No.: US 2025/0192061 A1
(43) Pub. Date: Jun. 12, 2025

(54) Semiconductor Module and Power Conversion Device

(71) Applicant: Hitachi Astemo, Ltd., Hitachinaka-shi, Ibaraki (JP)

(72) Inventors: Takeshi TOKUYAMA, Tokyo (JP); Takahiro ARAKI, Tokyo (JP); Shigehisa AOYAGI, Hitachinaka-shi, Ibaraki (JP); Toshiaki ISHII, Hitachinaka-shi, Ibaraki (JP)

(21) Appl. No.: 18/843,740

(22) PCT Filed: Apr. 13, 2023
(86) PCT No.: PCT/JP2023/015076

§ 371 Date: Sep. 4, 2024

(30) Foreign Application Priority Data
Jun. 16, 2022 (JP) 2022-097540

(51) Int. Cl. H01L 23/538; H01L 23/057; H01L 23/473; H01L 25/18

(52) U.S. Cl. CPC H01L 23/5385; H01L 23/057; H01L 23/5386; H01L 25/18; H01L 23/473

(57) ABSTRACT

Provided is a semiconductor module which realizes improvement in both heat dissipation and reliability. This semiconductor module comprises: a substrate (13) having DC wirings (14, 15) and AC wirings (16); and a semiconductor package (50). The substrate (13) has: a lamination region (61); and a connection region (62) having a terminal connection part (63) to be connected to a terminal. The connection region (62) has a first lamination wiring connection part (60) for electrically mutually connecting a plurality of the DC wirings (14, 15) or the AC wirings (16). The first lamination wiring connection part (60) is provided at a position not overlapping the terminal connection part (63) in the thickness direction of the substrate (13). A heat dissipation base (65) is disposed on the surface, of the substrate (13), opposite to the surface to be connected to the terminal, in a range that at least includes a position overlapping with the first lamination wiring connection part (60) in the thickness direction of the substrate (13).

### TECHNICAL FIELD

The present invention relates to a semiconductor module and a power conversion device.

### BACKGROUND ART

An inverter having a configuration in which a main circuit wiring is integrated on a printed circuit board can be integrated with a substrate because a joint can be omitted, and thus is an advantageous in being applicable to mass production. However, large current is required to flow through the wiring of the substrate, which results in a significant temperature change in the substrate. Thus, it is necessary to improve heat dissipation of the entire inverter including the substrate, to secure the reliability.

In the following PTL 1, there is disclosed a configuration in which a through hole is provided on one surface of a land on which a semiconductor package and a heat spreader are mounted, to improve heat dissipation of the semiconductor package that is solder-mounted.

### CITATION LIST

### Patent Literature

PTL 1: JP 2010-267869 A

### SUMMARY OF INVENTION

### Technical Problem

In the conventional configuration, during formation of a connection wiring of an inverter on a printed circuit board, a DC wiring through which large current flows and an AC wiring are layered from the viewpoint of reducing the inductance and reducing a wiring area. Because of this configuration, there is a problem of an increase of thermal distortion of a solder joint of the semiconductor package due to temperature rise in the substrate caused by heat generation of a wiring portion in the layered portion. Further, even though the semiconductor package can be satisfactorily cooled by being sandwiched between water channels on both sides thereof, the cooling is not enough to cool the inside of the substrate, which causes a problem in heat dissipation itself of the substrate. In view of this, it is an object of the present invention to provide a semiconductor module and a power conversion device that achieve both of improvement in heat dissipation and improvement in reliability.

### Solution to Problem

A semiconductor module includes a substrate including a DC wiring and an AC wiring, and a semiconductor package including a terminal connected to the DC wiring or the AC wiring, wherein the substrate includes a layered region where the DC wiring and the AC wiring are layered along a thickness direction of the substrate, and a connection region that is formed of the DC wiring or the AC wiring branching from the layered region on a plane of the substrate and includes a terminal connection portion where the DC wiring or the AC wiring is connected to the terminal, the connection region includes a first layered-wiring connection portion that penetrates along the thickness direction of the substrate and electrically connects the plurality of DC wirings or the plurality of AC wirings layered on the substrate to each other, the first layered-wiring connection portion is provided at a position not overlapping the terminal connection portion along the thickness direction of the substrate, and a heat dissipation base that dissipates heat from the DC wiring and the AC wiring is placed in a range including at least a position overlapping the first layered-wiring connection portion along the thickness direction of the substrate on a surface opposite to a surface of the substrate to which the terminal is connected.

### Advantageous Effects of Invention

According to the present invention, it is possible to provide a semiconductor module and a power conversion device that achieve both of improvement in heat dissipation and improvement in reliability.

### BRIEF DESCRIPTION OF DRAWINGS

FIG. 1 is an external perspective view of an inverter.

FIG. 2 is an internal view of the inverter.

FIG. 3 is a perspective view of a section taken along line A-A in FIG. 2.

FIG. 4 is a front view of the section of FIG. 3.

FIG. 5 is a view illustrating a positional relationship between cooling water channels and a main circuit unit.

FIG. 6 is a perspective view of a substrate of the main circuit unit.

FIG. 7 is an exploded view of a semiconductor package.

FIG. 8 is a plan view and a sectional view taken along line A-A of a substrate-integrated semiconductor module according to a first embodiment of the present invention.

FIG. 9 illustrates a first modification of FIG. 8.

FIG. 10 illustrates a second modification of FIG. 8.

FIG. 11 illustrates a third modification of FIG. 8.

FIG. 12 is a sectional view of a substrate-integrated semiconductor module according to a second embodiment of the present invention.

FIG. 13 is a plan view of a substrate-integrated semiconductor module according to a third embodiment of the present invention.

FIG. 14 is a sectional view taken along line B-B in FIG. 13.

Hereinafter, embodiments of the present invention will be described with reference to the drawings. The following description and drawings are examples for describing the present invention, and there are omission and simplification as appropriate for the sake of clarity of description. The present invention can be carried out in various other forms. Unless otherwise specified, each component may be provided singly or plurally.

In some cases, positions, sizes, shapes, ranges, and the like of the components illustrated in the drawings do not represent actual positions, sizes, shapes, ranges, and the like for the sake of facilitating understanding of the invention. Therefore, the present invention is not necessarily limited to the positions, sizes, shapes, ranges, and the like disclosed in the drawings.

### FIRST EMBODIMENT OF PRESENT INVENTION AND OVERALL CONFIGURATION OF DEVICE

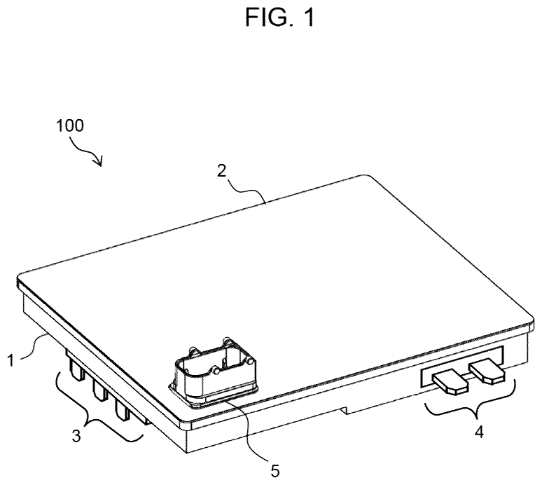

### (FIG. 1)

An inverter 100 includes components including a power conversion circuit unit and the like and a cooling water channel for cooling the components inside a housing 1. The components and the cooling water channel housed in the housing 1 are sealed in by a lid 2. An AC connector 3 and a DC connector 4 protrude from the housing 1, and a signal connector 5 protrudes from the lid 2.

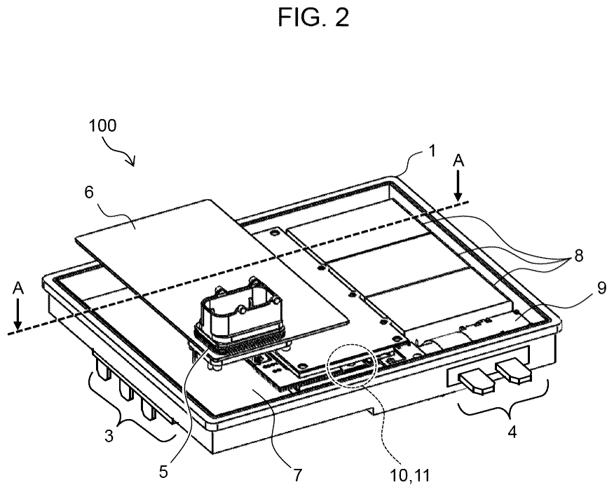

### (FIG. 2)

In the housing 1 of the inverter 100, a motor control board 6, a gate drive board 7, a smoothing capacitor 8, an EMC filter 9, a cooling water channel 10, and a main circuit unit 11 are placed. The motor control board 6 is mounted above the gate drive board 7, the cooling water channel 10, and the main circuit unit 11 in the drawing. The signal connector 5 is mounted on the motor control board 6, and the signal connector 5 penetrates the lid 2 and protrudes outwardly as illustrated in FIG. 1.

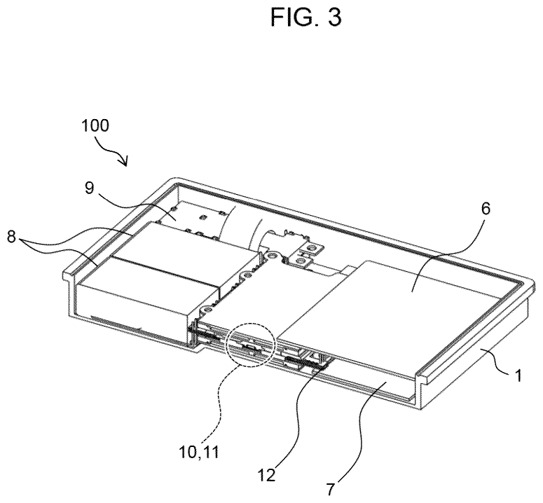

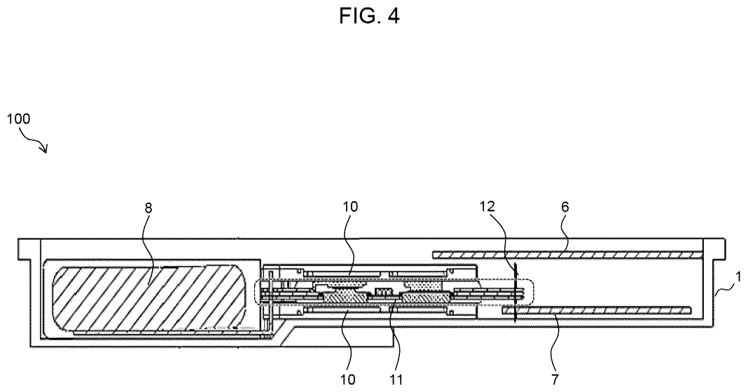

### (FIGS. 3 and 4)

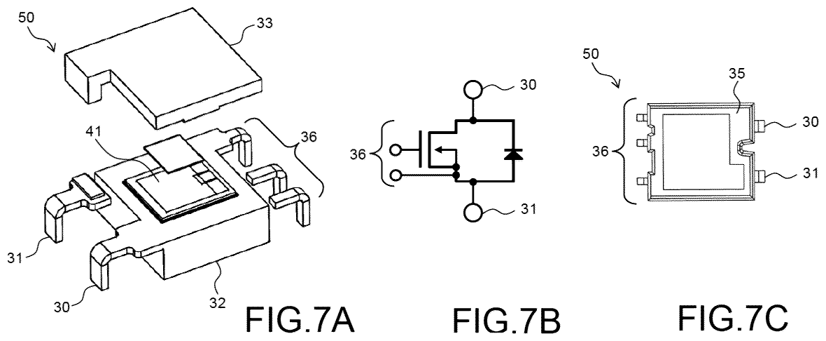

A substrate joining pin 12 is mounted on the gate drive board 7. The substrate joining pin 12 is electrically connected by a joining material such as solder in a substrate joining through hole 22 (described later with reference to FIG. 7) included in the main circuit unit 11.

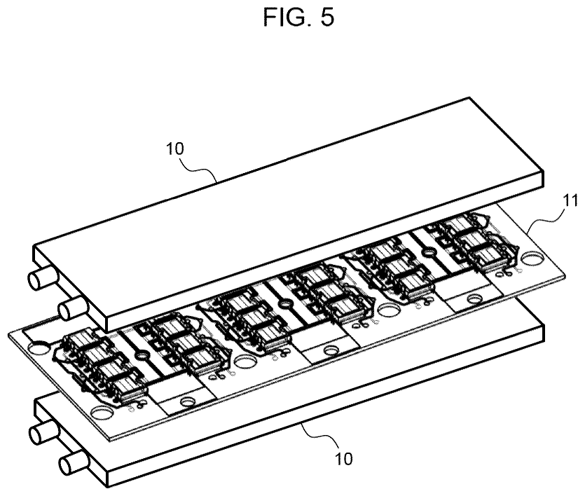

### (FIG. 5)

The main circuit unit 11 is sandwiched between the cooling water channels 10 to be fixed, is mounted on a substrate of the main circuit unit 11, and cools a circuit body including a power semiconductor element and each main circuit wiring.

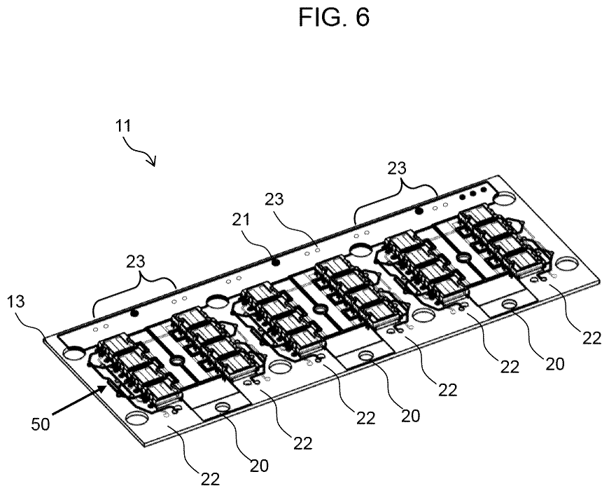

### (FIG. 6)

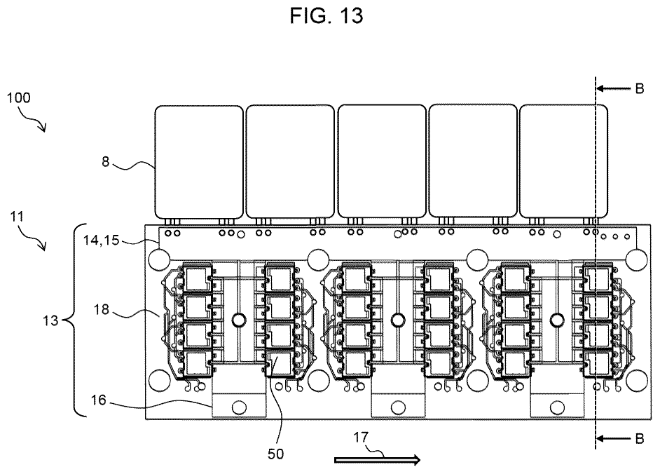

A semiconductor package 50 formed of a plurality of transfer-molded circuit bodies is mounted on a main circuit printed board 13 (substrate 13), so that the main circuit unit 11 functions as a semiconductor module. On the substrate 13, an AC connection portion 20 and a DC connection portion 21 are formed, and are electrically joined to an AC bus bar and a DC bus bar, respectively, by screw fastening. Further, the gate drive board 7 illustrated in FIG. 4 described above and the smoothing capacitor 8 illustrated in FIG. 13 describer later are electrically connected to the substrate joining through hole 22 and a capacitor joining through hole 23, respectively, by a joining material such as solder.

Note that the substrate joining through hole 22 is a through hole for connecting the substrate 13 to the gate drive board 7 via the substrate joining pin 12. Meanwhile, the capacitor joining through hole 23 is a through hole for connecting the substrate 13 to the smoothing capacitor 8.

### (FIG. 7)

FIG. 7(a) is an exploded view of the semiconductor package 50, FIG. 7(b) is a circuit diagram of a semiconductor element, and FIG. 7(c) is a view of the semiconductor package 50 being sealed with molding resin 35. The semiconductor package 50 includes a power semiconductor element 41 that is a silicon carbide MOSFET (SiC-MOS) element. The power semiconductor element 41 is placed between a first lead frame 32 and a second lead frame 33. The first lead frame 32 and the second lead frame 33 are connected to each other by respective connecting portions included therein.

The second lead frame 33 is provided with a pedestal electrode (not illustrated) in order to be connected to a surface electrode of the power semiconductor element 41 while keeping an insulation distance. The second lead frame 33 includes a first terminal 30 and a second terminal 31 that are in electrical conduction with the power semiconductor element 41 on one of side surfaces, and, in the same manner, includes a control signal terminal 36 that is in electrical conduction with the power semiconductor element 41 on the other side surface. The first terminal 30, the second terminal 31, and the control signal terminal 36 protrude from the second lead frame 33, and the respective protruding portions are electrically connected to the substrate 13, thereby performing switching control of the semiconductor package 50.

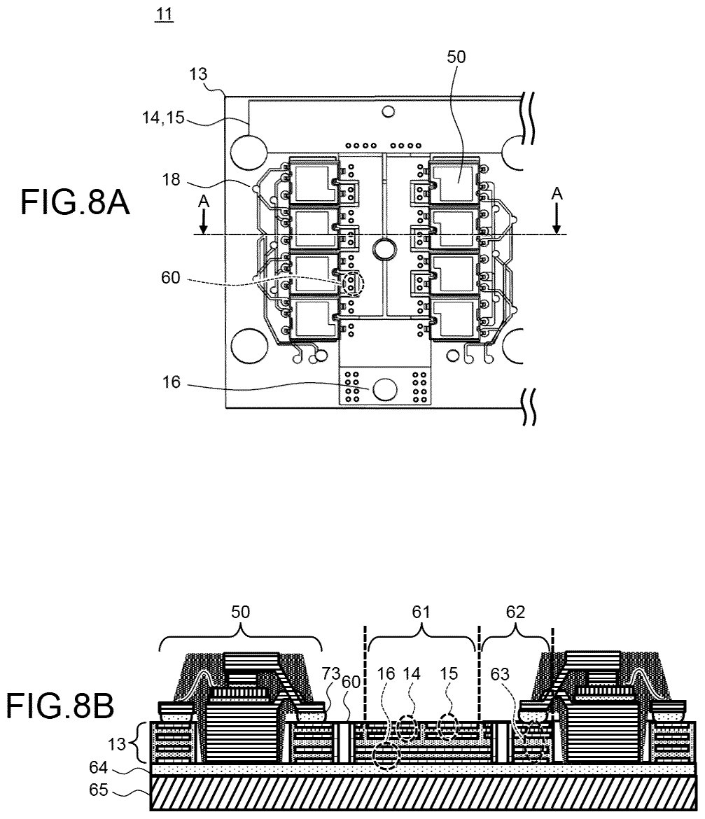

### (FIG. 8)

FIG. 8(a) is a plan view of the main circuit unit 11, and FIG. 8(b) is a sectional view taken along line A-A of FIG. 8(a). The substrate 13 of the main circuit unit 11 forming the semiconductor module includes a DC anode wiring pattern 14 (hereinafter referred to as a DC wiring 14), a DC cathode wiring pattern 15 (hereinafter referred to as a DC wiring 15), an AC wiring pattern 16 (hereinafter referred to as an AC wiring 16), and a control wiring pattern 18. Further, the substrate 13 includes the semiconductor package 50 including terminals connected to the DC wirings 14 and 15 or the AC wiring 16.

The substrate 13 has a layered wiring structure including the DC wirings 14 and 15 and the AC wiring 16, and hence, has a structure in which heat is easily generated. In addition to that, a portion between the semiconductor packages 50 is a region where the degree of heat generation is more likely to be high. It is required to reduce the influence of heat generated in the substrate 13 upon the semiconductor package 50 by efficiently dissipating the heat. According to the present invention, heat dissipation of the substrate 13 is promoted by inclusion of the following configuration.

The substrate 13 includes a layered region 61 where the DC wirings 14 and 15 and the AC wiring 16 are layered along a thickness direction of the substrate 13. Further, the substrate 13 includes a connection region 62 that is formed of the DC wirings 14 and 15 or the AC wiring 16 branching from the layered region 61 on the plane of the substrate 13 and includes a terminal connection portion 63 where the DC wirings 14 and 15 or the AC wiring 16 are connected to the terminals 30, 31, and 36.

Then, the connection region 62 includes a first layered-wiring connection portion 60 that electrically connects the plurality of DC wirings 14 and 15 or the plurality of AC wirings 16 that penetrate along the thickness direction of the substrate 13 and are layered on the substrate 13, to each other. The first layered-wiring connection portion 60 is provided at a position not overlapping the terminal connection portion 63 along the thickness direction of the substrate 13.

Because of inclusion of the first layered-wiring connection portion 60 between the semiconductor packages 50, in particular, in the substrate 13, wirings at the same potential that are electrically conductive from the top to the bottom of the substrate 13 are electrically connected. In addition to that, because of formation at a position close to the semiconductor package 50, fanned heat generated from each wiring of the substrate 13 is blocked. As a result, it is possible to suppress temperature rise of a solder joint 73 that is a connection portion between the semiconductor package 50 and the substrate 13. Moreover, solder distortion in the solder joint 73 can be reduced, so that the solder life can be extended.

Meanwhile, on a surface opposite to a surface of the substrate 13 to which the terminals 30, 31, and 36 are connected, a heat dissipation base 65 that dissipates heat from the DC wirings 14 and 15 and the AC wiring 16 is placed in a range including at least a position overlapping the first layered-wiring connection portion 60 along the thickness direction of the substrate 13. An insulating high thermal-conductive sheet 64 is placed between the heat dissipation base 65 and the substrate 13. As a result, heat of the substrate 13 can be transferred to the heat dissipation base 65 through the first layered-wiring connection portion 60, and the heat can be dissipated to the cooling water channel 10 described above in FIG. 5, so that temperature rise of the substrate 13 can be further suppressed.

### First Modification

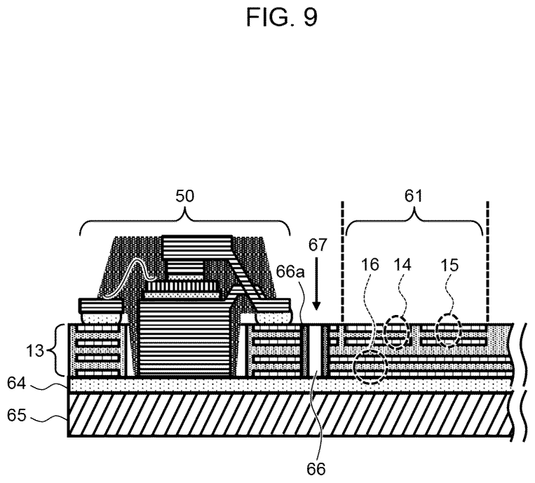

### (FIG. 9)

The first layered-wiring connection portion 60 is formed of a through hole 67. The through hole 67 is formed by processing of the substrate 13 to form a penetration hole 66 penetrating the substrate 13, and includes a plating film 66a on an inner side surface thereof. The plurality of DC wirings 14 and 15 or the plurality of AC wirings 16 are electrically connected to each other via the plating film 66a. As a result, the heat dissipation of the substrate 13 is improved in the same manner. Note that a space in the through hole 67 is filled with liquid resin, solder that is a meltable metallic joining material, or the like, and thus the thermal conductivity of the through hole 67 is improved. A material filling the space in the through hole 67 is not limited to that, and may be any material that can improve the thermal conductivity.

### Second Modification

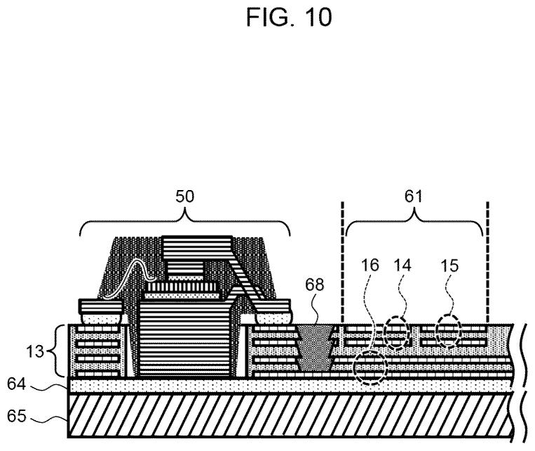

### (FIG. 10)

The first layered-wiring connection portion 60 is formed of a filled via 68 formed by filling of a penetration hole 27 penetrating the substrate 13 having been processed, with a plating layer. The plurality of DC wirings 14 and 15 or the plurality of AC wirings 16 are electrically connected to each other via the filled via 68. As a result, the heat dissipation of the substrate 13 is improved in the same manner.

### Third Modification

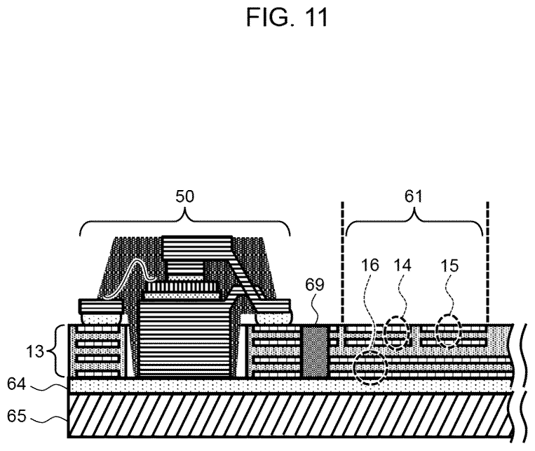

### (FIG. 11)

The first layered-wiring connection portion 60 can be realized by an inlay 69 formed by press-fitting a metallic post using, for example, copper, into the penetration hole 27 penetrating the substrate 13. The plurality of DC wirings 14 and 15 or the plurality of AC wirings 16 are electrically connected to each other via the inlay 69. As a result, the heat dissipation of the substrate 13 is improved in the same manner.

### SECOND EMBODIMENT

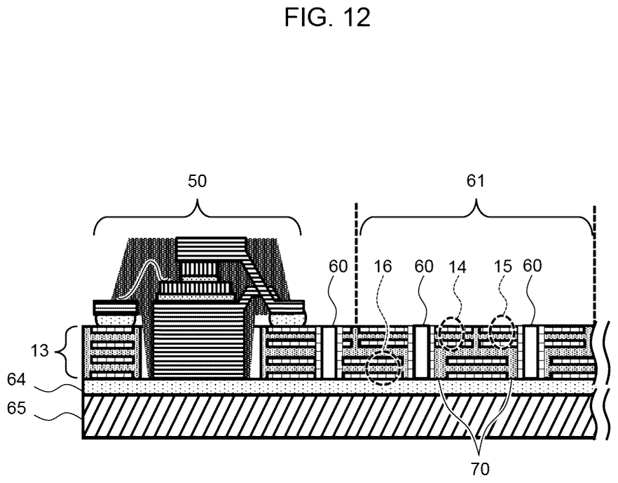

### (FIG. 12)

A second layered-wiring connection portion 60, different from the first layered-wiring connection portion 60 provided in the connection region 62, is further provided in the layered region 61. The second layered-wiring connection portion 60 is connected to any of the anode wiring 14, the cathode wiring 15, and the AC wiring 16, and is thermally connected to the heat dissipation base 65 on the surface opposite to the surface of the substrate 13 to which the terminals 30, 31, and 36 are connected.

In the substrate 13, in order to prevent connection to the same wiring not to have the same potential, when a certain wiring is connected by the second layered-wiring connection portion 60, a layered-wiring connection avoidance portion 70 is provided between another wiring being unconnected and the second layered-wiring connection portion 60 so that another wiring is not connected to the second layered-wiring connection portion 60. As a result, it is possible to avoid a short circuit caused by connecting wirings at different potentials to each other in the second layered-wiring connection portion 60 and to secure an insulation distance. In addition, because of this configuration, not only the connection region 62, but also the layered region 61 can be cooled, and the degree of heat dissipation of the substrate 13 can be increased as compared to that in the first embodiment.

### THIRD EMBODIMENT

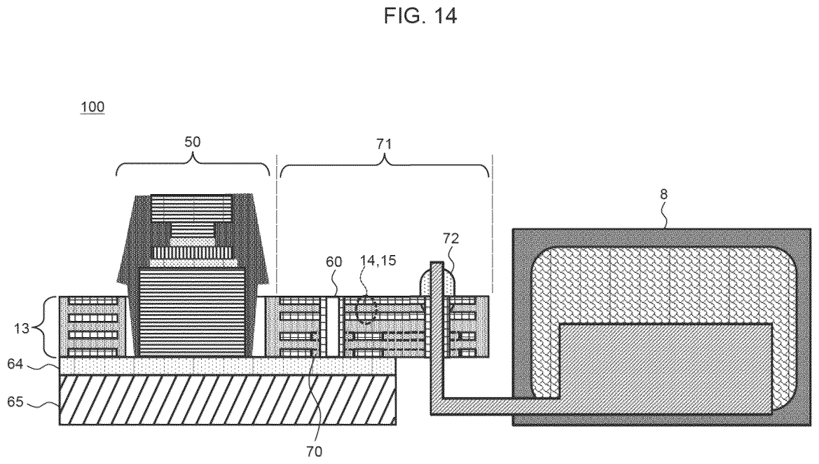

### (FIGS. 13 and 14)

In the power conversion device 100, the semiconductor packages 50 described in the first or second embodiment are placed such that the plurality of smoothing capacitors 8 are arranged side by side along the DC wirings 14 and 15 formed along a lengthwise direction 17 of the substrate 13 on the plane of the substrate 13.

A DC wiring layered region 71 is provided between the semiconductor package 50 and the smoothing capacitor 8. In the DC wiring layered region 71, a third layered-wiring connection portion 60 connected to a DC-wiring side of the substrate 13 is provided. Further, in the DC wiring layered region 71, a capacitor connection portion 72 that connects the substrate 13 and the smoothing capacitor 8 with a joining material such as solder is formed. The third layered-wiring connection portion 60 is provided between the semiconductor package 50 and the capacitor connection portion 72. Note that the third layered-wiring connection portion 60 is not connected to the AC wiring, and thus the layered-wiring connection avoidance portion 70 is provided between the third layered-wiring connection portion 60 and the AC wiring.

This allows the third layered-wiring connection portion 60 to dissipate heat generated in the substrate 13 with no influence of the heat upon the capacitor connection portion 72. Further, this enables both of improvement in heat dissipation and improvement in reliability not only in units of each semiconductor package 50 (semiconductor module), but also in units of each power conversion device 100 including the smoothing capacitor 8.

Note that the size of the layered-wiring connection portion 60 described above may be any predetermined size that does not interfere with wirings included in the substrate 13. Further, the configuration of the present invention may be applied to, for example, a boost converter in which the smoothing capacitors 8 are arranged in parallel along the lengthwise direction of the DC wirings 14 and 15 and a smoothing reactor is connected to the AC wiring pattern 16.

According to the first and second embodiments of the present invention described above, the following effects are produced.

(1) A semiconductor module includes the substrate 13 including the DC wirings 14 and 15 and the AC wiring 16, and the semiconductor package 50 including the terminals 30, 31, and 36 connected to the DC wirings 14 and 15 or the AC wiring 16. The substrate 13 includes the layered region 61 where the DC wirings 14 and 15 and the AC wiring 16 are layered along the thickness direction of the substrate 13, and the connection region 62 that is formed of the DC wirings 14 and 15 or the AC wiring 16 branching from the layered region 61 on the plane of the substrate 13 and includes the terminal connection portion 63 where the DC wirings 14 and 15 or the AC wiring 16 are connected to the terminals 30, 31, and 36. The connection region 62 includes the first layered-wiring connection portion 60 that electrically connects the plurality of DC wirings 14 and 15 or the plurality of AC wirings 16 that penetrate along the thickness direction of the substrate 13 and are layered on the substrate 13, to each other. The first layered-wiring connection portion 60 is provided at a position not overlapping the terminal connection portion 63 along the thickness direction of the substrate 13. On a surface opposite to a surface of the substrate 13 to which the terminals are connected, the heat dissipation base 65 that dissipates heat from the DC wirings 14 and 15 and the AC wiring 16 is placed in a range including at least a position overlapping the first layered-wiring connection portion 60 along the thickness direction of the substrate 13. With this configuration, it is possible to provide a semiconductor module that achieves both of improvement in heat dissipation and improvement in reliability.

(2) The first layered-wiring connection portion 60 includes the plating film 66a formed on the inner side surface of the penetration hole 66 penetrating the substrate 13, and electrically connects the plurality of DC wirings 14 and 15 or the plurality of AC wirings 16 to each other via the plating film 66a. With this configuration, the heat dissipation of the substrate 13 is improved.

(3) The first layered-wiring connection portion 60 includes the filled via 68 formed by filling of the penetration hole 66 penetrating the substrate 13 with a plating layer, and is connected to the plurality of DC wirings 14 and 15 or the plurality of AC wirings 16 via the filled via 68. With this configuration, the heat dissipation of the substrate 13 is improved.

(4) The first layered-wiring connection portion 60 includes the inlay 69 formed by press-fitting a metallic post into the penetration hole 66 penetrating the substrate 13, and electrically connects the plurality of DC wirings 14 and 15 or the plurality of AC wirings 16 to each other via the inlay 69. With this configuration, the heat dissipation of the substrate 13 is improved.

(5) The layered region 61 includes the second layered-wiring connection portion 60. The DC wirings include the anode wiring 14 and the cathode wiring 15, and the second layered-wiring connection portion 60 is connected to any of the anode wiring 14, the cathode wiring 15, and the AC wiring 16 and is thermally connected to the heat dissipation base 65 on the surface opposite to the surface of the substrate 13 to which the terminals 30, 31, and 36 are connected. In this manner, it is possible to avoid a short circuit caused by connecting wirings at different potentials, and to cool not only the connection region 62, but also the layered region 61 while securing an insulation distance, resulting in an increase of the degree of heat dissipation of the substrate 13.

(6) The power conversion device 100 includes the semiconductor modules that are placed such that the plurality of smoothing capacitors 8 are arranged side by side along the DC wirings 14 and 15 formed along the lengthwise direction of the substrate 13 on the plane of the substrate 13. With this configuration, both of improvement in heat dissipation and improvement in reliability can be achieved not only in units of each semiconductor package 50 (semiconductor module), but also in units of each power conversion device 100 including the smoothing capacitor 8.

Note that the present invention is not limited to the above-described embodiments, and various modifications and other configurations can be combined without departing from the gist of the present invention. In addition, the present invention is not limited to one including all the components described in the above-described embodiments, and includes one in which a part of the components is deleted.

### REFERENCE SIGNS LIST

1 housing
2 lid
3 AC connector
4 DC connector
5 signal connector
6 motor control board
7 gate drive board
8 smoothing capacitor
9 EMC filter
10 cooling water channel
11 main circuit unit
12 substrate joining pin
13 main circuit printed board
14 DC anode wiring pattern
15 DC cathode wiring pattern
16 AC wiring pattern
17 lengthwise direction of substrate
18 control wiring pattern
20 AC connection portion
21 DC connection portion
22 substrate joining through hole
23 capacitor joining through hole
30 first terminal
31 second terminal
32 first lead frame
33 second lead frame
35 molding resin
36 control signal terminal
41 power semiconductor element
50 semiconductor package
60 layered-wiring connection portion
61 layered region
62 connection region
63 terminal connection portion
64 high thermal-conductive sheet
65 heat dissipation base
66 penetration hole
66a plating film
67 through hole
68 filled via
69 inlay
70 layered-wiring connection avoidance portion
71 DC wiring layered region
72 capacitor connection portion
73 solder joint
100 inverter

1. A semiconductor module comprising:
a substrate including a DC wiring and an AC wiring; and
a semiconductor package including a terminal connected to the DC wiring or the AC wiring,
wherein the substrate includes a layered region where the DC wiring and the AC wiring are layered along a thickness direction of the substrate, and a connection region that is formed of the DC wiring or the AC wiring branching from the layered region on a plane of the substrate and includes a terminal connection portion where the DC wiring or the AC wiring is connected to the terminal,
the connection region includes a first layered-wiring connection portion that penetrates along the thickness direction of the substrate and electrically connects the plurality of DC wirings or the plurality of AC wirings layered on the substrate to each other,
the first layered-wiring connection portion is provided at a position not overlapping the terminal connection portion along the thickness direction of the substrate, and
a heat dissipation base that dissipates heat from the DC wiring and the AC wiring is placed in a range including at least a position overlapping the first layered-wiring connection portion along the thickness direction of the substrate on a surface opposite to a surface of the substrate to which the terminal is connected.

2. The semiconductor module according to claim 1, wherein the first layered-wiring connection portion includes a plating film formed on an inner side surface of a penetration hole penetrating the substrate, and electrically connects the plurality of DC wirings or the plurality of AC wirings to each other via the plating film.

3. The semiconductor module according to claim 1, wherein the first layered-wiring connection portion includes a filled via formed by filling of a penetration hole penetrating the substrate with a plating layer, and is connected to the plurality of DC wirings or the plurality of AC wirings via the filled via.

4. The semiconductor module according to claim 1, wherein the first layered-wiring connection portion includes an inlay formed by press-fitting a metallic post into a penetration hole penetrating the substrate, and electrically connects the plurality of DC wirings or the plurality of AC wirings to each other via the inlay.

5. The semiconductor module according to claim 1, wherein
the layered region includes a second layered-wiring connection portion,
the DC wiring includes an anode wiring and a cathode wiring, and
the second layered-wiring connection portion is connected to any of the anode wiring, the cathode wiring, and the AC wiring, and is thermally connected to the heat dissipation base on the surface opposite to the surface of the substrate to which the terminal is connected.

6. A power conversion device comprising
the semiconductor module according to claim 1,
wherein a plurality of smoothing capacitors are arranged side by side along the DC wiring formed along a lengthwise direction of the substrate on the plane of the substrate.
